(19) United States
(12) Patent Application Publication
(10) Pub. No.: US 2022/0406830 A1
(43) Pub. Date: Dec. 22, 2022

(54) PHOTORECEIVER ARRAY HAVING MICROLENSES

(71) Applicant: Allegro MicroSystems, LLC, Manchester, NH (US)

(72) Inventors: Bryan Cadugan, Bedford, NH (US); Harry Chandra, Phoenix, AZ (US); William P. Taylor, Amherst, NH (US)

(73) Assignee: Allegro MicroSystems, LLC, Manchester, NH (US)

(21) Appl. No.: 17/352,937

(22) Filed: Jun. 21, 2021

(51) Int. Cl. H01L 27/146; H04N 5/378

(52) U.S. Cl. CPC H01L 27/14627; H04N 5/378; H01L 27/14643

(57) ABSTRACT

Methods and apparatus for a first photodetector array die having pixels from a first end to a second end and a second photodetector array die having pixels from a first end to a second end. A readout integrated circuit (ROIC) can be electrically coupled to the first and second photodetector array die. One or more microlenses can steer light onto the photodetector arrays.

### BACKGROUND

As is known in the art, microlenses can be used to focus incoming light energy onto a detector array, which itself will generally have inactive area between pixels, resulting in some incident photonic energy not being detected by the array. For high-density applications, it is desirable for the microlenses to utilize the entire surface so that all incident light can be detected by the array, by focusing the light only on the active detector area. Close packing of microlenses can approach a fill factor of 100% so that boundaries between neighboring microlenses are in close contact. A fill-factor ratio refers to the active refracting area, which is the area that directs light to the photodetector array or total contiguous area occupied by the microlens array. Conventional detector arrays have fill factors below 100%.

A microlens refers to a lens having a diameter of less than a about a millimeter. A conventional microlens may comprise a single element with one planar surface and one spherical convex surface configured to refract light. A microlens having two flat and parallel surfaces with focusing obtained by a variation of the refractive index across the lens is referred to as gradient-index (GRIN) lense. So called micro-Fresnel lenses focus light by refraction in a set of concentric curved surfaces. Binary optic microlenses focus light by diffraction using stepped-edge grooves.

Conventional 1×512 arrays are known, however, InGaAs detector costs are prohibitive for such an array. Since most known dicing and packaging processing requires a maximum aspect ratio, and large linear arrays by nature have an extreme aspect ratio, significant die area is wasted. One attempt to reduce wasted die area uses use many smaller linear arrays, such as four 1×128, eight 1×64 or sixteen 1×32 arrays, which reduce the cost by four times for each 2× reduction in size. However, a disadvantage of this approach is that there will be “dead” area where the arrays are “butted” as closely as possible which creates undesirable gaps in the field of view. In conventional detectors there are typically gaps between active pixels that create the fill factor, but these gaps are typically on the order of 12 um, versus about 50-200 um or greater in a production packaging process where detectors are located on separate die.

### SUMMARY

Embodiments of the disclosure provide methods and apparatus for providing a photodetector system having a microlens structure that is space-efficient and cost effective. In embodiments, a detector system includes one lens per detector array so that the photonic energy applied to the lens is scaled to fit within the boundaries of each array. In other embodiments, a detector system includes one lens per detector element, where for each applicable area of incident photonic energy, the light is “steered” to land on each detector element. In this configuration, the elements near the edge of each array have the most amount of deflection and those in the center are simply working as ‘normal’ for microlenses to increase fill factor. In some embodiments, first and second layers of microlenses are provided on the detector array.

In some embodiments, microlenses are deposited on the underside of a glass substrate. This configuration can increase stability of the detector and enable the incident light on the package to hit a more uniform surface. In other embodiments, the microlenses are located on top of the substrate.

In one aspect, a system comprises: a first photodetector array die having pixels from a first end to a second end; a second photodetector array die having pixels from a first end to a second end; a readout integrated circuit (ROIC) electrically coupled to the first and second photodetector array die.

A system can further include one or more of the following features: a distance from the first end of the first photodetector array die and a pixel closest to the first end of the first photodetector array die is minimized, the first end of the first photodetector array die is sawed, the first end of the first photodetector array is etched, a distance between the first and second photodetector array die is minimized, the first and second photodetector array die are positioned next to each other so that a pitch of the pixels on first and second photodetector array die matches a pitch of a pixel in the first photodetector array die that is adjacent to a pixel in the second photodetector array die, a first microlens aligned with the first detector array die to steer light onto the pixels of the first photodetector array die and a second microlens aligned with the second detector array die to steer light onto the pixels of the second photodetector array die, an optically transparent substrate to support the first and second microlenses, the substrate comprises glass, a first microlens aligned with the first photodetector array to steer light onto the pixels of the first photodetector; and a second microlens aligned with the second photodetector array to steer light onto the pixels of the second photodetector, wherein the first and second microlens abut each other for eliminating gaps in which incident light does not reach any of the first and second photodetector arrays, the substrate has a first side opposite the first and second detector arrays and an opposing second side facing the first and second detector arrays, and wherein the first and second microlens are on the first side of the substrate, the substrate has a first side opposite the first and second detector arrays and an opposing second side facing the first and second detector arrays, and wherein the first and second microlens are on the second side of the substrate, and/or the system comprises an integrated circuit package.

In another aspect, a system comprises: a first photodetector array having pixels; a second photodetector array having pixels; and a first structure including a first group of microlens positioned such that each one of the microlens is aligned with a respective pixel of the first photodetector array to steer light onto the pixels of the first photodetector array, wherein there is at least one microlens for each of the pixels in the first photodetector array; and a second structure including a second group of microlens positioned such that each one of the microlens is aligned with a respective pixel of the second photodetector array to steer light onto the pixels of the second photodetector array.

A system can further include one or more of the following features: a readout integrated circuit (ROIC) electrically coupled to the first and second photodetector arrays, an optically transparent substrate to support the first and second structures, the substrate comprises glass, the substrate has a first side opposite the first and second detector arrays and an opposing second side facing the first and second detector arrays, and wherein the first and second structure are on the first side of the substrate, the substrate has a first side opposite the first and second detector arrays and an opposing second side facing the first and second detector arrays, and wherein the first and second structure are on the second side of the substrate, the system comprises an integrated circuit package, the first structure includes a supporting substrate having a linear first side to contact the transparent substrate and an opposing non-linear second side to support the microlens, the non-linear second side of the supporting substrate includes a series of regions to support respective ones of the microlenses, the regions have respective angles in relation to a surface of the transparent substrate, and/or respective angles of the regions increase as the supported microlens are located further from a center of the first photodetector array.

In a further aspect, a method comprises: employing a first photodetector array die having pixels from a first end to a second end; employing a second photodetector array die having pixels from a first end to a second end; and electrically coupling a readout integrated circuit (ROIC) to the first and second photodetector array die.

A method can further include one or more of the following features: minimizing a distance from the first end of the first photodetector array die and a pixel closest to the first end of the first photodetector array die, sawing the first end of the first photodetector array die, etching the first end of the first photodetector array, minimizing a distance between the first and second photodetector array die, the first and second photodetector array die are positioned next to each other so that a pitch of the pixels on first and second photodetector array die matches a pitch of a pixel in the first photodetector array die that is adjacent to a pixel in the second photodetector array die, aligning a first microlens with the first detector array die to steer light onto the pixels of the first photodetector array die and aligning a second microlens with the second detector array die to steer light onto the pixels of the second photodetector array die, an optically transparent substrate to support the first and second microlenses, the substrate comprises glass, aligning a first microlens with the first photodetector array to steer light onto the pixels of the first photodetector; and aligning a second microlens with the second photodetector array to steer light onto the pixels of the second photodetector, wherein the first and second microlens abut each other for eliminating gaps in which incident light does not reach any of the first and second photodetector arrays, the substrate has a first side opposite the first and second detector arrays and an opposing second side facing the first and second detector arrays, and wherein the first and second microlens are on the first side of the substrate, the substrate has a first side opposite the first and second detector arrays and an opposing second side facing the first and second detector arrays, and wherein the first and second microlens are on the second side of the substrate, and/or the system comprises an integrated circuit package.

In another aspect, a method comprises: employing a first photodetector array having pixels; employing a second photodetector array having pixels; and positioning a first structure including a first group of microlens such that each one of the microlens is aligned with a respective pixel of the first photodetector array to steer light onto the pixels of the first photodetector array, wherein there is at least one microlens for each of the pixels in the first photodetector array; and positioning a second structure including a second group of microlens such that each one of the microlens is aligned with a respective pixel of the second photodetector array to steer light onto the pixels of the second photodetector array.

A method can further include one or more of the following features: employing a readout integrated circuit (ROIC) electrically coupled to the first and second photodetector arrays, an optically transparent substrate to support the first and second structures, the substrate comprises glass, the substrate has a first side opposite the first and second detector arrays and an opposing second side facing the first and second detector arrays, and wherein the first and second structure are on the first side of the substrate, the substrate has a first side opposite the first and second detector arrays and an opposing second side facing the first and second detector arrays, and wherein the first and second structure are on the second side of the substrate, the system comprises an integrated circuit package, the first structure includes a supporting substrate having a linear first side to contact the transparent substrate and an opposing non-linear second side to support the microlens, the non-linear second side of the supporting substrate includes a series of regions to support respective ones of the microlenses, the regions have respective angles in relation to a surface of the transparent substrate, and/or respective angles of the regions increase as the supported microlens are located further from a center of the first photodetector array.

### BRIEF DESCRIPTION OF THE DRAWINGS

The foregoing features of this disclosure, as well as the disclosure itself, may be more fully understood from the following description of the drawings in which:

FIGS. 1A and 1B are cross-sectional view of prior art photodetectors;

FIG. 2 is a cross-sectional view of a photodetector system having a microlens for each detector array;

FIG. 2A is a cross-sectional view of a further photodetector system having a microlens for each detector array;

FIG. 2B is a schematic representation of pixel dimensions for pixels in a detector array;

FIG. 3 is a cross-sectional view of a photodetector system having a microlens for each detector array pixel;

FIG. 4 is a cross-sectional view of a photodetector system having a compound microlens for each detector array pixel;

FIG. 5 shows additional detail for a compound microlens shown in FIG. 4;

FIG. 5A shows an example micro-Fresnel microlens for photodetector system;

FIG. 5B is a isometric view and FIG. 5C is a top view of an example microlens array that can be used in a photodetector system;

FIG. 5D is a top view of an example one dimensional (1D) 1×4 detector die in a 15 die, 3×5 array 552;

FIG. 6 is a cross-sectional view of a detector array; and

FIG. 7 is a cross-sectional view of a series of sub arrays.

### DETAILED DESCRIPTION

Prior to describing example embodiments of the disclosure some information is provided. Laser ranging systems can include laser radar (ladar), light-detection and ranging (lidar), and rangefinding systems, which are generic terms for the same class of instrument that uses light to measure the distance to objects in a scene. This concept is similar to radar, except optical signals are used instead of radio waves. Similar to radar, a laser ranging and imaging system emits a pulse toward a particular location and measures the return echoes to extract the range.

Laser ranging systems generally work by emitting a laser pulse and recording the time it takes for the laser pulse to travel to a target, reflect, and return to a photoreceiver. The laser ranging instrument records the time of the outgoing pulse—either from a trigger or from calculations that use measurements of the scatter from the outgoing laser light—and then records the time that a laser pulse returns. The difference between these two times is the time of flight to and from the target. Using the speed of light, the round-trip time of the pulses is used to calculate the distance to the target.

Lidar systems may scan the beam across a target area to measure the distance to multiple points across the field of view, producing a full three-dimensional range profile of the surroundings. More advanced flash lidar cameras, for example, contain an array of detector elements, each able to record the time of flight to objects in their field of view.

When using light pulses to create images, the emitted pulse may intercept multiple objects, at different orientations, as the pulse traverses a 3D volume of space. The echoed laser-pulse waveform contains a temporal and amplitude imprint of the scene. By sampling the light echoes, a record of the interactions of the emitted pulse is extracted with the intercepted objects of the scene, allowing an accurate multi-dimensional image to be created. To simplify signal processing and reduce data storage, laser ranging and imaging can be dedicated to discrete-return systems, which record only the time of flight (TOF) of the first, or a few, individual target returns to obtain angle-angle-range images. In a discrete-return system, each recorded return corresponds, in principle, to an individual laser reflection (i.e., an echo from one particular reflecting surface, for example, a tree, pole or building). By recording just a few individual ranges, discrete-return systems simplify signal processing and reduce data storage, but they do so at the expense of lost target and scene reflectivity data. Because laser-pulse energy has significant associated costs and drives system size and weight, recording the TOF and pulse amplitude of more than one laser pulse return per transmitted pulse, to obtain angle-angle-range-intensity images, increases the amount of captured information per unit of pulse energy. All other things equal, capturing the full pulse return waveform offers significant advantages, such that the maximum data is extracted from the investment in average laser power. In full-waveform systems, each backscattered laser pulse received by the system is digitized at a high sampling rate (e.g., 500 MHz to 1.5 GHz). This process generates digitized waveforms (amplitude versus time) that may be processed to achieve higher-fidelity 3D images.

Of the various laser ranging instruments available, those with single-element photoreceivers generally obtain range data along a single range vector, at a fixed pointing angle. This type of instrument—which is, for example, commonly used by golfers and hunters—either obtains the range (R) to one or more targets along a single pointing angle or obtains the range and reflected pulse intensity (I) of one or more objects along a single pointing angle, resulting in the collection of pulse range-intensity data, (R, I)ᵢ, where i indicates the number of pulse returns captured for each outgoing laser pulse.

More generally, laser ranging instruments can collect ranging data over a portion of the solid angles of a sphere, defined by two angular coordinates (e.g., azimuth and elevation), which can be calibrated to three-dimensional (3D) rectilinear cartesian coordinate grids; these systems are generally referred to as 3D lidar and ladar instruments. The terms “lidar” and “ladar” are often used synonymously and, for the purposes of this discussion, the terms “3D lidar,” “scanned lidar,” or “lidar” are used to refer to these systems without loss of generality. 3D lidar instruments obtain three-dimensional (e.g., angle, angle, range) data sets. Conceptually, this would be equivalent to using a rangefinder and scanning it across a scene, capturing the range of objects in the scene to create a multi-dimensional image. When only the range is captured from the return laser pulses, these instruments obtain a 3D data set (e.g., angle, angle, range)n, where the index n is used to reflect that a series of range-resolved laser pulse returns can be collected, not just the first reflection.

Some 3D lidar instruments are also capable of collecting the intensity of the reflected pulse returns generated by the objects located at the resolved (angle, angle, range) objects in the scene. When both the range and intensity are recorded, a multi-dimensional data set [e.g., angle, angle, (range-intensity)ₙ] is obtained. This is analogous to a video camera in which, for each instantaneous field of view (FOV), each effective camera pixel captures both the color and intensity of the scene observed through the lens. However, 3D lidar systems, instead capture the range to the object and the reflected pulse intensity.

Lidar systems can include different types of lasers, including those operating at different wavelengths, including those that are not visible (e.g., those operating at a wavelength of 840 nm or 905 nm), and in the near-infrared (e.g., those operating at a wavelength of 1064 nm or 1550 nm), and the thermal infrared including those operating at wavelengths known as the “eyesafe” spectral region (i.e., generally those operating at a wavelength beyond 1300-nm), where ocular damage is less likely to occur. Lidar transmitters are generally invisible to the human eye. However, when the wavelength of the laser is close to the range of sensitivity of the human eye—roughly 350 nm to 730 nm—the energy of the laser pulse and/or the average power of the laser must be lowered such that the laser operates at a wavelength to which the human eye is not sensitive. Thus, a laser operating at, for example, 1550 nm, can—without causing ocular damage—generally have 200 times to 1 million times more laser pulse energy than a laser operating at 840 nm or 905 nm.

One challenge for a lidar system is detecting poorly reflective objects at long distance, which requires transmitting a laser pulse with enough energy that the return signal—reflected from the distant target—is of sufficient magnitude to be detected. To determine the minimum required laser transmission power, several factors must be considered. For instance, the magnitude of the pulse returns scattering from the diffuse objects in a scene is proportional to their range and the intensity of the return pulses generally scales with distance according to 1/R\hat{ }4 for small objects and 1/R\hat{ }2 for larger objects; yet, for highly-specularly reflecting objects (i.e., those objects that are not diffusively-scattering objects), the collimated laser beams can be directly reflected back, largely unattenuated. This means that—if the laser pulse is transmitted, then reflected from a target 1 meter away—it is possible that the full energy (J) from the laser pulse will be reflected into the photoreceiver; but—if the laser pulse is transmitted, then reflected from a target 333 meters away—it is possible that the return will have a pulse with energy approximately 10\hat{ }12 weaker than the transmitted energy. To provide an indication of the magnitude of this scale, the 12 orders of magnitude (10\hat{ }12) is roughly the equivalent of: the number of inches from the earth to the sun, 10× the number of seconds that have elapsed since Cleopatra was born, or the ratio of the luminous output from a phosphorescent watch dial, one hour in the dark, to the luminous output of the solar disk at noon.

In many cases of lidar systems highly-sensitive photoreceivers are used to increase the system sensitivity to reduce the amount of laser pulse energy that is needed to reach poorly reflective targets at the longest distances required, and to maintain eyesafe operation. Some variants of these detectors include those that incorporate photodiodes, and/or offer gain, such as avalanche photodiodes (APDs) or single-photon avalanche detectors (SPADs). These variants can be configured as single-element detectors,-segmented-detectors, linear detector arrays, or area detector arrays. Using highly sensitive detectors such as APDs or SPADs reduces the amount of laser pulse energy required for long-distance ranging to poorly reflective targets. The technological challenge of these photodetectors is that they must also be able to accommodate the incredibly large dynamic range of signal amplitudes.

As dictated by the properties of the optics, the focus of a laser return changes as a function of range; as a result, near objects are often out of focus. Furthermore, also as dictated by the properties of the optics, the location and size of the “blur”—i.e., the spatial extent of the optical signal—changes as a function of range, much like in a standard camera. These challenges are commonly addressed by using large detectors, segmented detectors, or multi-element detectors to capture all of the light or just a portion of the light over the full-distance range of objects. It is generally advisable to design the optics such that reflections from close objects are blurred, so that a portion of the optical energy does not reach the detector or is spread between multiple detectors. This design strategy reduces the dynamic range requirements of the detector and prevents the detector from damage.

Acquisition of the lidar imagery can include, for example, a 3D lidar system embedded in the front of car, where the 3D lidar system, includes a laser transmitter with any necessary optics, a single-element photoreceiver with any necessary dedicated or shared optics, and an optical scanner used to scan (“paint”) the laser over the scene. Generating a full-frame 3D lidar range image—where the field of view is 20 degrees by 60 degrees and the angular resolution is 0.1 degrees (10 samples per degree)—requires emitting 120,000 pulses [(20*10*60*10)=120,000)]. When update rates of 30 frames per second are required, such as is required for automotive lidar, roughly 3.6 million pulses per second must be generated and their returns captured.

There are many ways to combine and configure the elements of the lidar system—including considerations for the laser pulse energy, beam divergence, detector array size and array format (single element, linear, 2D array), and scanner to obtain a 3D image. If higher power lasers are deployed, pixelated detector arrays can be used, in which case the divergence of the laser would be mapped to a wider field of view relative to that of the detector array, and the laser pulse energy would need to be increased to match the proportionally larger field of view. For example—compared to the 3D lidar above—to obtain same-resolution 3D lidar images 30 times per second, a 120,000-element detector array (e.g., 200×600 elements) could be used with a laser that has pulse energy that is 120,000 times greater. The advantage of this “flash lidar” system is that it does not require an optical scanner; the disadvantages are that the larger laser results in a larger, heavier system that consumes more power, and that it is possible that the required higher pulse energy of the laser will be capable of causing ocular damage. The maximum average laser power and maximum pulse energy are limited by the requirement for the system to be eyesafe.

As noted above, while many lidar system operate by recording only the laser time of flight and using that data to obtain the distance to the first target return (closest) target, some lidar systems are capable of capturing both the range and intensity of one or multiple target returns created from each laser pulse. For example, for a lidar system that is capable of recording multiple laser pulse returns, the system can detect and record the range and intensity of multiple returns from a single transmitted pulse. In such a multi-pulse lidar system, the range and intensity of a return pulse from a from a closer-by object can be recorded, as well as the range and intensity of later reflection(s) of that pulse—one(s) that moved past the closer-by object and later reflected off of more-distant object(s). Similarly, if glint from the sun reflecting from dust in the air or another laser pulse is detected and mistakenly recorded, a multi-pulse lidar system allows for the return from the actual targets in the field of view to still be obtained.

The amplitude of the pulse return is primarily dependent on the specular and diffuse reflectivity of the target, the size of the target, and the orientation of the target. Laser returns from close, highly-reflective objects, are many orders of magnitude greater in intensity than the intensity of returns from distant targets. Many lidar systems require highly sensitive photodetectors, for example avalanche photodiodes (APDs), which along with their CMOS amplification circuits. So that distant, poorly-reflective targets may be detected, the photoreceiver components are optimized for high conversion gain. Largely because of their high sensitivity, these detectors may be damaged by very intense laser pulse returns.

For example, if an automotive equipped with a front-end lidar system were to pull up behind another car at a stoplight, the reflection off of the license plate may be significant—perhaps 10\hat{ }12 higher than the pulse returns from targets at the distance limits of the lidar system. When a bright laser pulse is incident on the photoreceiver, the large current flow through the photodetector can damage the detector, or the large currents from the photodetector can cause the voltage to exceed the rated limits of the CMOS electronic amplification circuits, causing damage. For this reason, it is generally advisable to design the optics such that the reflections from close objects are blurred, so that a portion of the optical energy does not reach the detector or is spread between multiple detectors.

However, capturing the intensity of pulses over a larger dynamic range associated with laser ranging may be challenging because the signals are too large to capture directly. One can infer the intensity by using a recording of a bit-modulated output obtained using serial-bit encoding obtained from one or more voltage threshold levels. This technique is often referred to as time-over-threshold (TOT) recording or, when multiple-thresholds are used, multiple time-over-threshold (MTOT) recording.

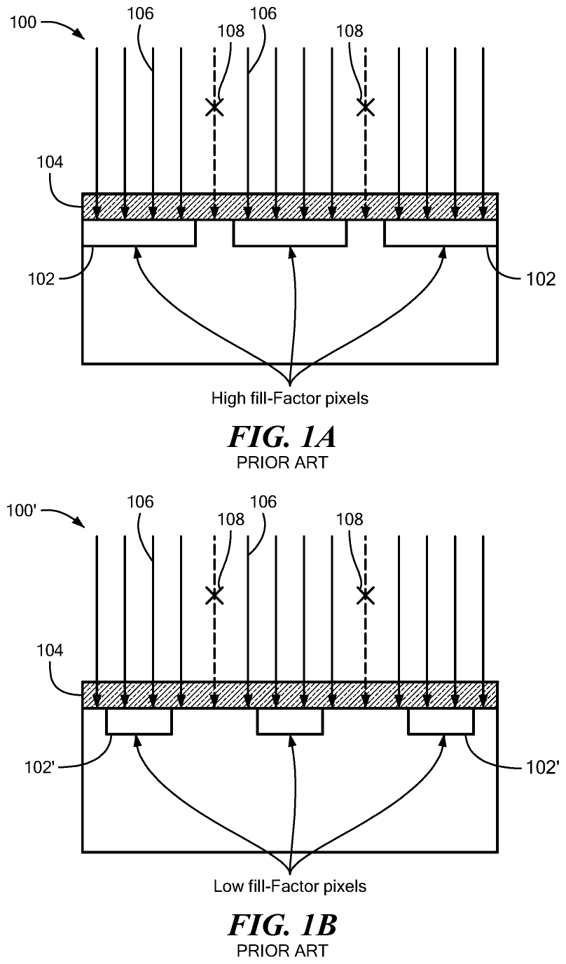

FIGS. 1A and 1B show prior art photodetectors 100, 100′ having a series of detector arrays 102, 102′ below a transparent substrate 104, such as glass. Incident light 106 impinges on the surface of the substrate 104 and onto the detector arrays. Due to space between adjacent detector arrays 102, some incident light 108 passes through the substrate without landing on a detector 102, e.g., a non-photosensitive area.

The amount of area in which light incident on the substrate does not land on a detector can be defined by a so-called fill factor, such as the percent of active area vs. total area. The detector 100 shown in FIG. 1A has a higher fill factor than the detector 100′ shown in FIG. 1B. As can be seen, there is smaller spacing between the arrays 102 in the detector 100 of FIG. 1A than the arrays 102′ in the detector 100′ of FIG. 1B.

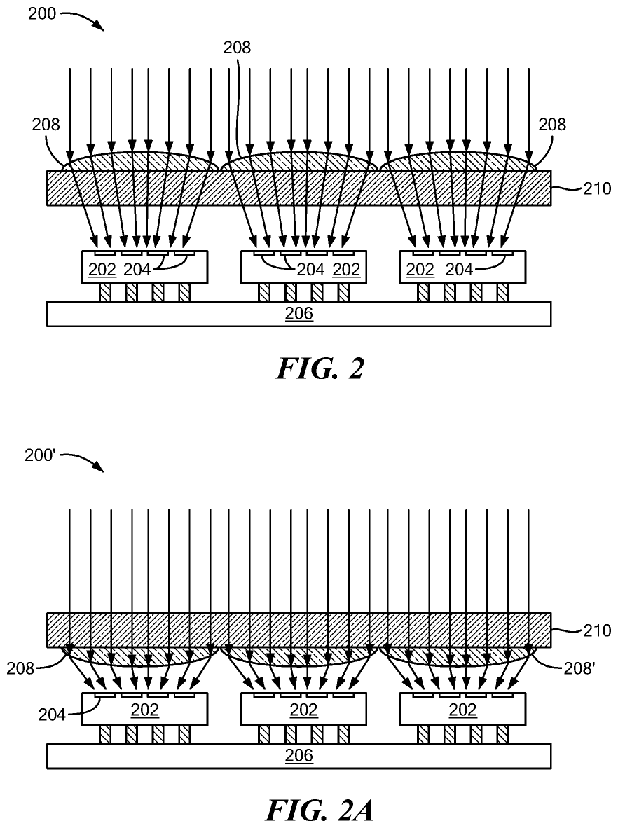

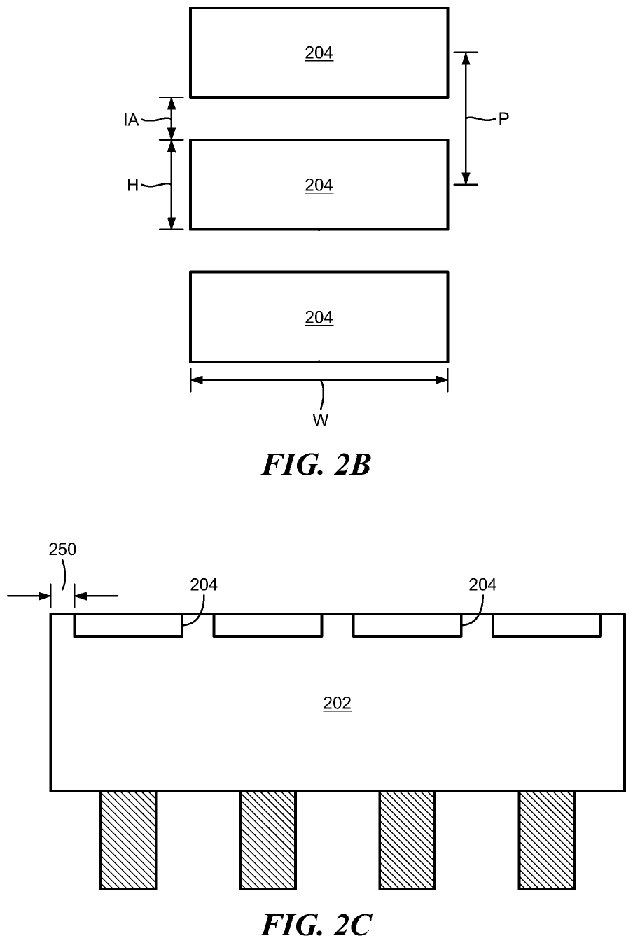

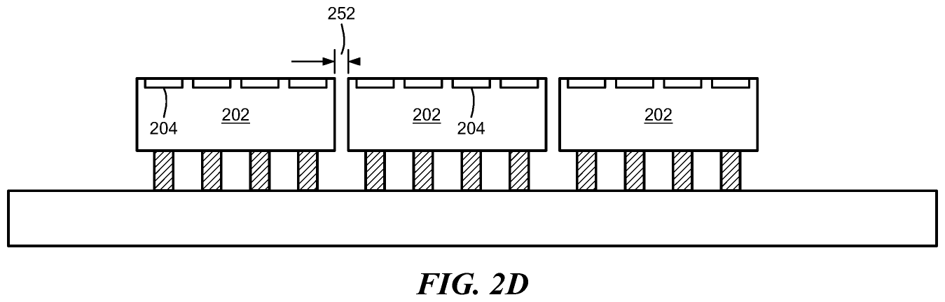

FIG. 2 shows a sensor system 200 including a series of photodetector arrays 202 having pixels 204 for detecting light. In embodiments, the photodetector arrays 202 can be coupled to a readout integrated circuit (ROIC) 206. A series of microlens 208 can be located on an exterior of the sensor system 200 through which light can travel onto the pixels 204 of the detector arrays. In embodiments, the microlenses 208 can be supported by a transparent substrate 210, such as glass.

The substrate 210 allows an IC package embodiment to be sealed. The microlenses 208 steer incident light to a desired optical path onto the detector arrays 202. In the illustrated embodiment, there is dead space between pixels 204 and space between adjacent detector arrays 202. In the illustrated embodiment, the arrays are hybridized by providing a direct connection to the ROIC 206.

In the illustrated embodiment, one microlens 208 is provided for each photodetector array 202. The example microlenses 208 have a flat surface for contacting the substrate 210 and a convex surface for refracting incident light. In the illustrated embodiment, edges of the microlenses 208 abut each other so that substantially all incident light is steered onto one of the detector arrays 202.

FIG. 2A shows an embodiment 200′ having microlenses 208′ underneath the substrate 210 facing the detector arrays 202. The microlenses 208′ steer light onto the detector arrays 202. A detector IC package can be sealed as noted above.

In another aspect, the spacing of a pixel from the edge of a die can be decreased compared with conventional arrays. By having the pixel closer to the die-edge, die can be placed closer together to reduce the amount of light going to non-photosensitive areas.

FIG. 2B shows an example arrangement of a pixels 304 having a width W and a height H. There is an inactive area IA between adjacent pixels 204. A pitch P defines a distance from center-to-center of each pixel. In an example embodiment, a photoreceiver is defined as H=24 um, W=100 μm, IA=6 μm and P=30 μm. With this arrangement, the fill factor is 24/30 or 80%.

It is understood that any practical parameters for height, width, aspect ratio, and pitch can be used to meet the needs of a particular application. In embodiments, one or more of these parameters can vary from pixel to pixel and/or array to array.

FIGS. 2C and 2D show an alternate embodiment in which the photoreceiver die 202 has a smaller spacing 250 from the pixels on the end of the die as compared to the spacing shown in FIG. 2. Any practical cutting mechanism can be used. For example, in the case of a silicon wafer, a DRIE (deep reactive ion etching) process may be used cut the wafers instead of a saw to allow more accurate “dicing” or separation of the die from the wafer.

Since the spacing 250 from the pixel to the end of the die is reduced, detector arrays 202 can be spaced 252 more closely than, for example, the arrangement shown in FIG. 2. With reduced non-photosensitive area, and detector array die 202 closer together, fill factor may be improved. In addition, in some embodiments, which may have a larger pitch, pixel-to-pixel spacing on a detector array 202 may match pixel-to-pixel spacing. That is, all pixels across all arrays have the same spacing.

The die 202 may be placed close together, using for example, but not limited to, a vacuum wand tool on a die attach machine during the manufacture. The pixels 204 near the edge of the die 202 may be closer to the edge of the die than a standard IC process in order to maintain the optical pixel spacing required. If the placement is such that adjacent die may be within for example, but not limited to 5 um (microns), and the pixel spacing on the die is a such that adjacent pixels are, for example, 10 um, 20 um, 30 um or larger than the pixel array may comprise multiple die without adversely affecting the spacing.

In some embodiments, optics, such as a microlens, can be used to change the optics, such as the focal length of a lens, to change pixel spacing and/or pitch. For example, pixel spacing can increase to greater than 6 um and the pitch can increase to greater than about 30 um.

It is understood that any suitable material can be used, such as Si, InGaAs, InGaAsP, and Ge and alloys thereof, and the like. It is understood that other suitable materials may become known. In embodiments, the detector configuration and materials can enable hybridization to a ROIC.

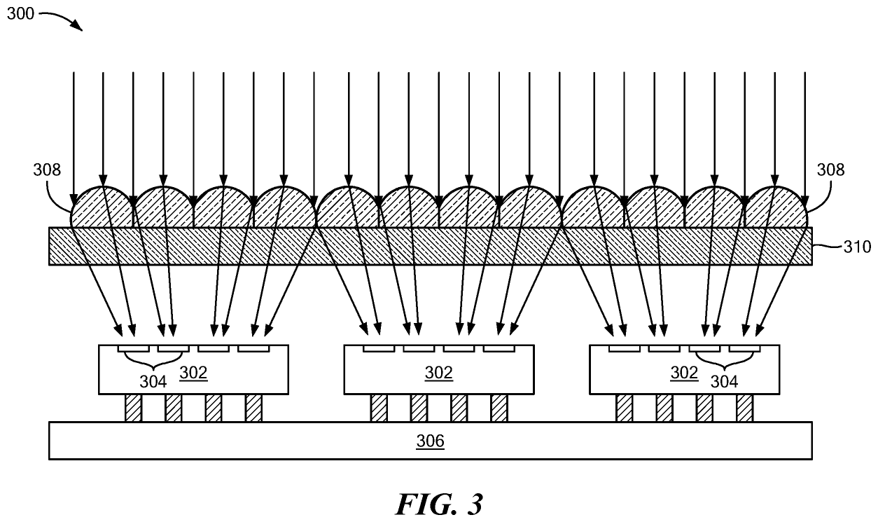

FIG. 3 shows a sensor system 300 including a series of photodetector arrays 302 having pixels 304 for detecting light. In embodiments, the photodetector arrays 302 can be coupled to a readout integrated circuit (ROIC) 306. A series of microlens 308 is supported by a transparent substrate 310, such as glass. In the illustrated embodiment, there is one microlens 308 for each pixel 304 on the detector arrays 302. The microlenses 308 focus incident light onto active areas of the pixels 304.

It is understood that the focus of the microlenses 308 can vary to meet the needs of a particular application. For example, the microlenses 308 may focus incident light onto a particular point or may focus to a wider area.

With this arrangement, dead space between active pixels is mitigated resulting in a higher fill factor as compared to other configurations. This is because in addition to ensuring that as little incident light as possible impacts the area between the detector array die, it is also ensured that the light does not impact the gaps between the pixels. In the illustrated embodiment, the microlenses 308 abut each other so that substantially all incident light is steered onto the active area of one of the detector arrays 302. In addition, cost savings can be realized by using a series of smaller 1D arrays.

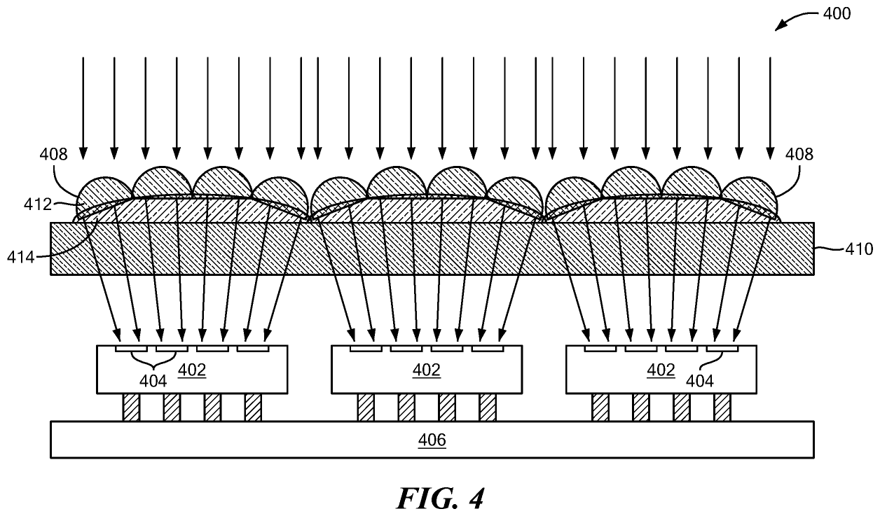

FIG. 4 shows a sensor system 400 including a series of photodetector arrays 402 having pixels 404 for detecting light. In embodiments, the photodetector arrays 402 can be coupled to a ROIC 406. A series of microlens 408 is supported by a transparent substrate 410. In the illustrated embodiment, there is one microlens 408 for each pixel 404 on the detector arrays 402. The microlenses 408 focus incident light onto active areas of the pixels 404.

In the illustrated embodiment, at least some of the microlenses 408 have a compound structure. For example, a microlens 408a may have a first portion 412 that is similar to the microlens 308 of FIG. 3 and a second portion 414 that angles the first portion to achieve desired focusing characteristics.

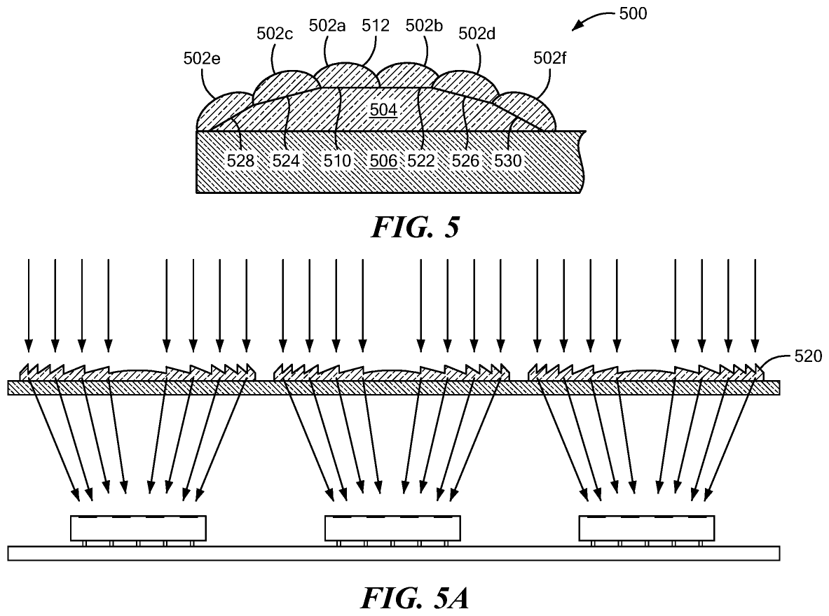

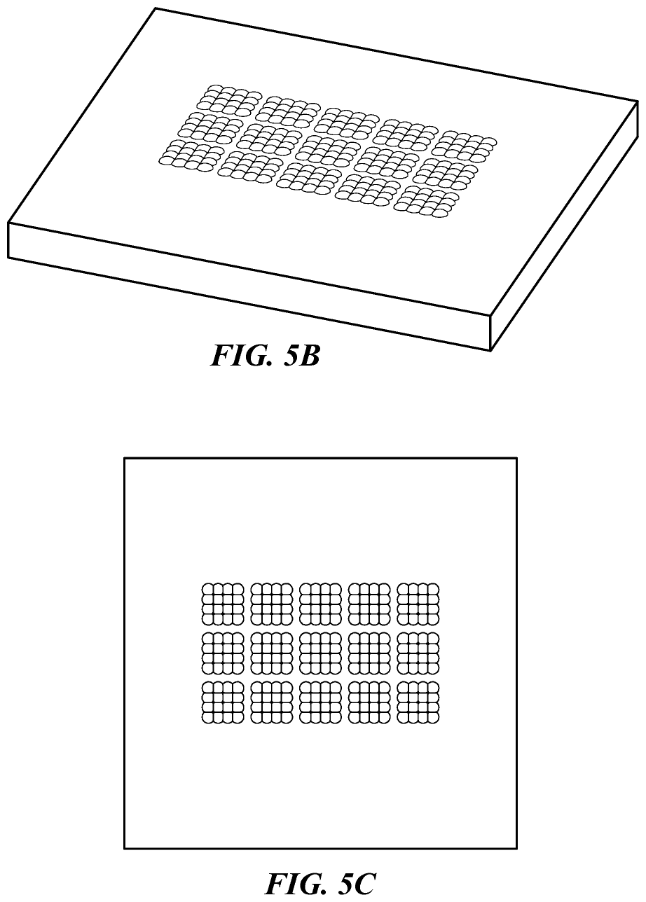

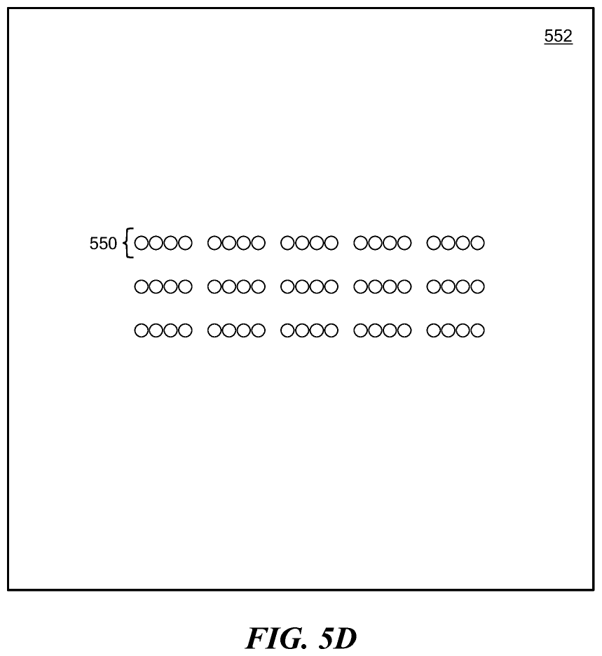

FIG. 5 shows a portion of an example compound microlens structure 500 having a series of microlenses 502a-f on a multi-surface structure 504 supported by a substrate 506. First and second microlenses 502a, b abut each other in the middle region of the structure 500. The first microlens 502a has a flat bottom surface 510 and a convex top surface 512. The other microlenses 502 may have a similar configuration.

The multi-surface structure 504 includes respective surfaces configured to support a particular microlens 502 at a given angle for achieving desired focusing characteristics. For example, in the illustrated embodiment, the multisurface structure 504 includes a first surface 522 that is parallel to a surface of the substrate 506. The first surface 522 is of sufficient area so that the first and second microlenses 502a, b can abut each other. The multisurface structure 504 includes a second surface 524 and a third surface 526 at complementary angles with respect to each other. The second surface 524 supports the third microlens 502c and the third surface 526 supports the fourth microlens 502d. A fourth surface 528 has a complementary angle with a fifth surface 530 for supporting the respective fifth and sixth microlenses 502e, f. In order to steer the incident light onto the detector arrays (not shown), the angle of the lens-supporting surfaces increases with respect to the substrate surface as lenses 502 are located closer to the edge of the detector.

In some embodiments, the multisurface structure 504 is a discrete component to which the microlenses 502 are bonded. In other embodiments, the microlens structure 500 is fabricated as an integrated component.

It is understood that the multisurface structure 504 can have any practical number of surfaces at any desired angle for supporting microlenses to meet the needs of a particular application.

It is understood that any suitable microlens type can be used, such as the microlens of FIG. 2, a (GRIN) mirolens, a micro-Fresnel microlens 520 (see FIG. 5A), a binary optic microlens, and the like. Example microlens elements can be fabricated in many different ways, such as discrete lens creation and attach, growth through reflow, using a mask or 3D printing, etching to pattern the less, etc. In one example embodiment, the lenses can be placed on a glass, for example, window associated with the package and aligned to the underlying detector arrays. It is understood that the lenses can be placed in any suitable location, such as built onto the die. In other embodiments, the lenses can form a window.

FIGS. 5B and 5C show an example microlens array that can be used to steer light onto photodetector die, as describe above. It is understood that the illustrated microlens are not to scale and intended to shown example embodiments to facilitate an understanding of the disclosure.

It is understood that any suitable die and pixel configuration can be used to meet the needs of a particular application. FIG. 5D shows an example one dimensional (1D) 1×4 detector die in a 15 die, 3×5 array 552. As noted above, the die can be separated by cutting, etching, or other suitable technique.

Embodiments of the disclosure provide significant cost reductions compared with conventional detectors. For example, InGaAs wafers can cost more than $10K each for a three inch wafer, which corresponds to about $2.25 per square mm. In comparison, an eight inch silicon wafer may cost in the order of about $700 or about $0.02 per square mm. This cost factor often makes InGaAs (or any specialty photodetector material) the most expensive part of the overall product. When fabricating large 1D Focal Plane Arrays (FPAs) using a hybridized or bonded Silicon Read Out IC (ROIC) to an InGaAs Detector array, this detector array is dominant in the overall cost. In addition, a large 1D array has an aspect ratio that is incompatible with handling of the material which amplifies the cost issue.

For example, a conventional detector array with a 30 um pitch may have a width of around 120 um, but with a roughly 16 mm height for 512 pixels (in one example), the width will need to be 4 mm to maintain a fairly aggressive 4:1 aspect ratio. Comparing 4 mm to 120 um shows that roughly 97% of this expensive detector material will be wasted. The aspect ratio can be defined as the long dimension vs. the small dimension of the die. Generally dicing and assembly vendors do not like large aspect ratios because it becomes difficult to handle the die without breakage and may impose minimum aspect ratios.

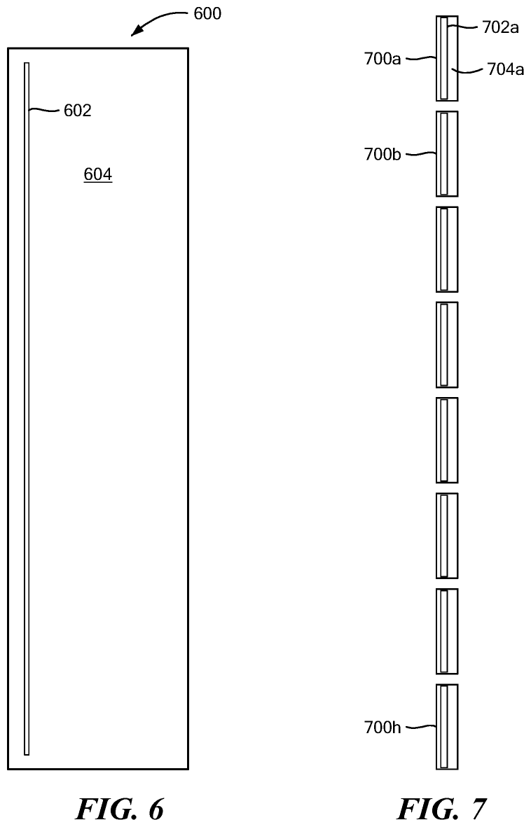

FIG. 6 shows a conventional 1×512 detector array 600 at a 30 um pitch with an active area 602 and detector material 604. As noted above, detector material 604 is the most costly component of the detector. The area 604 beyond the active area 602 is wasted, inactive area. The total dimensions are 16 mm by 4 mm for a total area of 64 mm\hat{ }2. This amounts to over 97% of wasted inactive area.

FIG. 7 shows an example detector having eight 1×64 arrays, each with a 4:1 aspect ratio for a size of 2.12 mm×0.53 mm. Additional area of the detector material 704 is consumed to enable appropriate surround of the active area 702 on the top and bottom. A gap between arrays 700 is driven by tolerances for placing individual die. In embodiments, in the 1D optical field there are no gaps in the sensed area.

The total detector area in the illustrated embodiment is about 9 mm\hat{ }2 or an 86% reduction in wasted area for a commensurate cost reduction as wasted inactive area is about 80% in this case.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A system, comprising:
a first photodetector array die having pixels from a first end to a second end;
a second photodetector array die having pixels from a first end to a second end;
a readout integrated circuit (ROIC) electrically coupled to the first and second photodetector array die.

2. The system according to claim 1, wherein a distance from the first end of the first photodetector array die and a pixel closest to the first end of the first photodetector array die is minimized.

3. The system according to claim 2, wherein the first end of the first photodetector array die is sawed.

4. The system according to claim 2, wherein the first end of the first photodetector array is etched.

5. The system according to claim 1, wherein a distance between the first and second photodetector array die is minimized.

6. The system according to claim 1, wherein the first and second photodetector array die are positioned next to each other so that a pitch of the pixels on first and second photodetector array die matches a pitch of a pixel in the first photodetector array die that is adjacent to a pixel in the second photodetector array die.

7. The system according to claim 1, further including a first microlens aligned with the first detector array die to steer light onto the pixels of the first photodetector array die and a second microlens aligned with the second detector array die to steer light onto the pixels of the second photodetector array die.

8. The system according to claim 1, further including an optically transparent substrate to support the first and second microlenses.

9. The system according to claim 8, wherein the substrate comprises glass.

10. The system according to claim 1, further including:
a first microlens aligned with the first photodetector array to steer light onto the pixels of the first photodetector; and
a second microlens aligned with the second photodetector array to steer light onto the pixels of the second photodetector,
wherein the first and second microlens abut each other for eliminating gaps in which incident light does not reach any of the first and second photodetector arrays.

11. The system according to claim 10, wherein the substrate has a first side opposite the first and second detector arrays and an opposing second side facing the first and second detector arrays, and wherein the first and second microlens are on the first side of the substrate.

12. The system according to claim 10, wherein the substrate has a first side opposite the first and second detector arrays and an opposing second side facing the first and second detector arrays, and wherein the first and second microlens are on the second side of the substrate.

13. The system according to claim 1, wherein the system comprises an integrated circuit package.

14. A system, comprising:
a first photodetector array having pixels;
a second photodetector array having pixels; and
a first structure including a first group of microlens positioned such that each one of the microlens is aligned with a respective pixel of the first photodetector array to steer light onto the pixels of the first photodetector array, wherein there is at least one microlens for each of the pixels in the first photodetector array; and
a second structure including a second group of microlens positioned such that each one of the microlens is aligned with a respective pixel of the second photodetector array to steer light onto the pixels of the second photodetector array.

15. The system according to claim 14, further including a readout integrated circuit (ROIC) electrically coupled to the first and second photodetector arrays.

16. The system according to claim 14, further including an optically transparent substrate to support the first and second structures.

17. The system according to claim 14, wherein the substrate comprises glass.

18. The system according to claim 14, wherein the substrate has a first side opposite the first and second detector arrays and an opposing second side facing the first and second detector arrays, and wherein the first and second structure are on the first side of the substrate.

19. The system according to claim 14, wherein the substrate has a first side opposite the first and second detector arrays and an opposing second side facing the first and second detector arrays, and wherein the first and second structure are on the second side of the substrate.

20. The system according to claim 14, wherein the system comprises an integrated circuit package.

21. The system according to claim 14, wherein the first structure includes a supporting substrate having a linear first side to contact the transparent substrate and an opposing non-linear second side to support the microlens.

22. The system according to claim 21, wherein the non-linear second side of the supporting substrate includes a series of regions to support respective ones of the microlenses.

23. The system according to claim 22, wherein the regions have respective angles in relation to a surface of the transparent substrate.

24. The system according to claim 23, wherein respective angles of the regions increase as the supported microlens are located further from a center of the first photodetector array.

25. A method, comprising:
employing a first photodetector array die having pixels from a first end to a second end;
employing a second photodetector array die having pixels from a first end to a second end; and
electrically coupling a readout integrated circuit (ROIC) to the first and second photodetector array die.

26. The method according to claim 25, further including minimizing a distance from the first end of the first photodetector array die and a pixel closest to the first end of the first photodetector array die.

27. The method according to claim 26, further including sawing the first end of the first photodetector array die.

28. The method according to claim 26, further including etching the first end of the first photodetector array.

29. The method according to claim 25, further including minimizing a distance between the first and second photodetector array die.

30. The method according to claim 25, wherein the first and second photodetector array die are positioned next to each other so that a pitch of the pixels on first and second photodetector array die matches a pitch of a pixel in the first photodetector array die that is adjacent to a pixel in the second photodetector array die.

31. The method according to claim 25, further including aligning a first microlens with the first detector array die to steer light onto the pixels of the first photodetector array die and aligning a second microlens with the second detector array die to steer light onto the pixels of the second photodetector array die.

32. The method according to claim 25, further including employing an optically transparent substrate to support the first and second microlenses.

33. The method according to claim 32, wherein the substrate comprises glass.

34. The method according to claim 25, further including:
aligning a first microlens with the first photodetector array to steer light onto the pixels of the first photodetector; and
aligning a second microlens with the second photodetector array to steer light onto the pixels of the second photodetector,
wherein the first and second microlens abut each other for eliminating gaps in which incident light does not reach any of the first and second photodetector arrays.

35. The method according to claim 34, wherein the substrate has a first side opposite the first and second detector arrays and an opposing second side facing the first and second detector arrays, and wherein the first and second microlens are on the first side of the substrate.

36. The method according to claim 34, wherein the substrate has a first side opposite the first and second detector arrays and an opposing second side facing the first and second detector arrays, and wherein the first and second microlens are on the second side of the substrate.

37. The method according to claim 25, wherein the system comprises an integrated circuit package.

38. A method, comprising:
employing a first photodetector array having pixels;
employing a second photodetector array having pixels; and
positioning a first structure including a first group of microlens such that each one of the microlens is aligned with a respective pixel of the first photodetector array to steer light onto the pixels of the first photodetector array, wherein there is at least one microlens for each of the pixels in the first photodetector array; and
positioning a second structure including a second group of microlens such that each one of the microlens is aligned with a respective pixel of the second photodetector array to steer light onto the pixels of the second photodetector array.

39. The method according to claim 38, further including employing a readout integrated circuit (ROIC) electrically coupled to the first and second photodetector arrays.

40. The method according to claim 38, further including an optically transparent substrate to support the first and second structures.

41. The method according to claim 38, wherein the substrate comprises glass.

42. The method according to claim 38, wherein the substrate has a first side opposite the first and second detector arrays and an opposing second side facing the first and second detector arrays, and wherein the first and second structure are on the first side of the substrate.

43. The method according to claim 38, wherein the substrate has a first side opposite the first and second detector arrays and an opposing second side facing the first and second detector arrays, and wherein the first and second structure are on the second side of the substrate.

44. The method according to claim 38, wherein the system comprises an integrated circuit package.

45. The method according to claim 38, wherein the first structure includes a supporting substrate having a linear first side to contact the transparent substrate and an opposing non-linear second side to support the microlens.

46. The method according to claim 45, wherein the non-linear second side of the supporting substrate includes a series of regions to support respective ones of the microlenses.

47. The method according to claim 46, wherein the regions have respective angles in relation to a surface of the transparent substrate.

48. The method according to claim 47, wherein respective angles of the regions increase as the supported microlens are located further from a center of the first photodetector array.
